(19) United States
(12) Patent Application Publication
(10) Pub. No.: US 2026/0371540 A1
(43) Pub. Date: Nov. 19, 2026

(54) Shielded Enclosure

(71) Applicant: CenCore Group, LLC, Springville, UT (US)

(72) Inventors: Jesse Sanders, Springville, UT (US); Adam Fife, Springville, UT (US)

(73) Assignee: CenCore Group, LLC, Springville, UT (US)

(21) Appl. No.: 19/452,192

(22) Filed: Jan. 16, 2026

Related U.S. Application Data
(63) Continuation-in-part of application No. 19/209,770, filed on May 15, 2025, now Pat. No. 12,557,255.

(51) Int. Cl. H05K 9/00

(52) U.S. Cl. CPC H05K 9/0003

(57) ABSTRACT

A shielded enclosure door apparatus includes a metallic outer door panel box and a metallic inner door panel non-metallically coupled to the metallic outer door panel, the inner door panel facing an interior workspace. The shielded enclosure door apparatus further includes an air gap between the metallic inner door panel and the metallic outer door panel.

### BACKGROUND

Current technologies have yet to reach the full capabilities necessary for a secure compartmentalized area for critical communications in environments where sensitive or potentially classified information is discussed. There are many situations where secure communications are required or desired. In military, government, corporate, and intelligence sectors, unauthorized access to confidential conversations and other communications can lead to severe consequences, including national security threats, data breaches, and corporate espionage. A secure area ensures that discussions and data transmissions remain protected from surveillance, interception, or leakage.

One of the primary reasons for having a secure compartmentalized space is to prevent electronic eavesdropping. In today's digital age, adversaries use sophisticated surveillance techniques, and new technologies are needed to ensure communications and trade secrets are kept safe from increasingly advanced interception methods. Designing and constructing a shielded enclosure presents a significant challenge, particularly when trying to strike a balance between effectiveness, size, and cost. While larger enclosures can offer more room for operations and better isolation, they also demand considerably more materials—such as specialized shielding panels, acoustic insulation, structural supports, and filtration components—all of which can drive up both material and labor costs.

Moreover, as the physical footprint of the enclosure increases, so does the complexity of maintaining uniform shielding performance across all surfaces, including the ceiling, floor, and especially seams and joints. This introduces more potential points of failure and increases the likelihood of electromagnetic transmission leakage or acoustic vulnerabilities. One solution is a carefully optimized enclosure that uses just enough material to ensure high-performance shielding without becoming overly large, heavy, or expensive. This requires precise engineering and thoughtful material selection to ensure every component—from wall panels to cable entry points—contributes to the overall integrity of the shield while maintaining cost-efficiency

### SUMMARY

A shielded enclosure panel is disclosed. Embodiments of the invention include a shielded enclosure panel that is used as part of a wall that separates an interior workspace (alternatively called a work area, production space, or protected area) from a surrounding environment. Some embodiments of the invention work in conjunction with a shielded enclosure which is in its simplest form box that separates an interior workspace and, in some cases, includes an outer box and an inner box. The shielded enclosure is described in a companion patent application concurrently filed by the inventors herewith and entitled “Shielded Enclosure”. As a general description of the shielded enclosure, the outer box (alternatively called an exterior box, exterior metallic box, shipping container, ISO container, shield line exterior box) surrounds and encloses the inner box (alternatively called an interior box, interior metallic box, shield line interior box). The outer box includes at least one door or area of ingress/egress to access the inner box. The inner box surrounds and encloses the interior workspace. The inner box includes at least one door or area of ingress/egress to access the interior workspace. Embodiments of the shielded enclosure panel may be used for the outer box or the inner box or both.

In some embodiments, the shielded enclosure panel includes a first metal sheet and a second metal sheet coupled to the first metal sheet and enclosing a cavity. The shielded enclosure panel includes a first electromagnetic transmission interference (EMI) absorber on an inside surface of the first metal sheet and a second EMI absorber on an inside surface of the second metal sheet. In some embodiments, the shielded enclosure panel includes a waveguide positioned between the first and second EMI absorbers and acoustic insulation positioned between the waveguide and each EMI absorber.

In some embodiments, the first metal sheet and the second metal sheet may be welded closed to enclose the cavity.

In some embodiments, the cavity may be fully sealed.

In some embodiments, the EMI absorber may be a flat absorber and comprises ferrite.

In some embodiments, the shielded enclosure door produces an electromagnetic transmission attenuation between 9 kHz and 40 gHz.

In some embodiments, the waveguide cells include an airgap.

In some embodiments, the acoustic insulation is mineral wool.

In some embodiments, the waveguide may comprise a honeycomb pattern with a cell size with at least a first dimension of between 1/16″ to 1″ and second dimension of between ½ to 3″ such as, for example, a first dimension of ⅛″ and a second dimension of 1″.

In some embodiments, the first and second metal sheet may be 304 stainless steel.

In some embodiments, the first and second metal sheet may be 14-gauge steel.

In some embodiments, the shielded enclosure panel includes a panel box including a first metal sheet forming a first side of the panel box and a second metal sheet forming a second side of the panel box with a gap therebetween. In some embodiments, the shielded enclosure panel includes a first EMI absorber on an inside surface of the first metal sheet and a second EMI absorber on an inside surface of the second metal sheet. In some embodiments, the shielded enclosure panel includes a waveguide positioned between the first and second EMI absorbers and acoustic insulation positioned between the waveguide and each EMI absorber.

In some embodiments, the shielded enclosure panel includes a first metal sheet and a second metal sheet coupled to the first metal sheet and enclosing a cavity. In some embodiments, the shielded enclosure panel includes a first EMI absorber on an inside surface of the first metal sheet and a second EMI absorber on an inside surface of the second metal sheet. In some embodiments, the shielded enclosure panel includes a waveguide positioned between the first and second EMI absorbers and acoustic insulation positioned between the waveguide and each EMI absorber and wherein the shielded enclosure panel produces an electromagnetic transmission attenuation between 9 kHz and 40 gHz (e.g., in the RF range).

In some embodiments, a shielded enclosure panel may include a first metal sheet and a second metal sheet continuously bonded to the first metal sheet around a periphery of the first metal sheet and a periphery of the second metal sheet defining a cavity. The shielded enclosure may also include a waveguide having a honeycomb pattern disposed within the cavity without being in contact with the first metal sheet or the second metal sheet.

In some embodiments, the shielded enclosure panel may include a first EMI absorber disposed within the cavity between the waveguide and cither or both the first metal sheet and the second metal sheet.

In some embodiments, the shielded enclosure panel may include an acoustic insulation disposed within the cavity between the waveguide and either or both the first metal sheet and the second metal sheet.

In some embodiments, the second metal sheet may be welded to the first metal sheet around a periphery of the first metal sheet.

In some embodiments, the second metal sheet may be bonded to the first metal sheet around a periphery of the first metal sheet with a gasket and plurality of bolts.

In some embodiments, the shielded enclosure panel may include acoustic insulation disposed within the cavity between the waveguide and the either or both the first metal sheet and the second metal sheet.

In some embodiments, the acoustic insulation may include mineral wool.

In some embodiments, the shielded enclosure panel may include the shielded enclosure panel may produces an electromagnetic transmission attenuation between 9 kHz and 40 gHz.

In some embodiments, the shielded enclosure panel may include the shielded enclosure panel may have an STC rating of greater than about 40 or above or about 55 or above.

In some embodiments, a shielded enclosure panel may include a first metal sheet; a second metal sheet continuously bonded to the first metal sheet around a periphery of the first metal sheet and a periphery of the second metal sheet defining a cavity; and a waveguide disposed within the cavity without being in contact with the first metal sheet or the second metal sheet. The shielded enclosure panel may produce an electromagnetic transmission attenuation between 9 kHz and 40 gHz. The shielded enclosure panel may have an STC rating of greater than about 40 or above or about 55 or above.

The various embodiments described in the summary and this document are provided not to limit or define the disclosure or the scope of the claims.

### BRIEF DESCRIPTION OF THE FIGURES

These and other features, aspects, and advantages of the present disclosure are better understood when the following Detailed Description is read with reference to the accompanying drawings.

FIG. 1 is a perspective view of a shielded enclosure system according to some embodiments.

FIG. 2 is a perspective cutaway view of a shielded enclosure system showing the entry vestibule according to some embodiments.

FIG. 3 is a perspective view of a shielded enclosure system showing the according to some embodiments.

FIG. 4 is a perspective view of a shielded enclosure system according to some embodiments.

FIG. 5 is a perspective view of a shielded enclosure system according to some embodiments.

FIG. 6 shows a perspective view of a shielded enclosure system according to some embodiments.

FIG. 7 is a perspective view of a shielded enclosure system according to some embodiments.

FIG. 8 is a schematic diagram of a cross section of a shielded enclosure system according to some embodiments.

FIG. 9 is a schematic diagram of cross section of panel and I-beam construction according to some embodiments.

FIG. 10 is a side view of a cutaway of a shielded enclosure panel according to some embodiments.

FIG. 11 is a perspective view of a shielded enclosure panel according to some embodiments.

FIG. 12 is a front view of a plurality of shielded enclosure panels welded together according to some embodiments.

### DETAILED DESCRIPTION

Embodiments of the invention include a shielded enclosure panel and systems that are used with overall shielded enclosures which separate an interior workspace (alternatively called a work area, production space, or protected area) from a surrounding environment. Some embodiments of the invention include generally a panel that can be used on one or both of the two boxes of a shielded enclosure system, the two boxes being an outer box and an inner box that work together to separate and enclose the interior workspace from the surrounding environment. The outer box (also called herein an exterior box, exterior metallic box, shipping container, ISO container, outer shield line, or shield line exterior box) surrounds and encloses the inner box (also called herein an interior box, interior metallic box, inner shield line, or shield line interior box). The outer box includes at least one door or area of ingress/egress to access the inner box. The inner box surrounds and encloses the interior workspace. The inner box includes at least one door or area of ingress/egress to access the interior workspace. Embodiments of these panels are disclosed herein.

The interior workspace may be used for any work or communications that require isolation from a surrounding area that may be subject to sophisticated surveillance technologies. Any type of work may be conducted within the interior workspace. The interior workspace may include computer terminals or other types of electronic devices upon which a user can conduct work that is intended to be kept secret or isolated from the surrounding environment. Uses of the interior workspace may include but are not limited to government espionage, military, business, corporate, and/or other activities that are intended to remain free from external surveillance.

For businesses, protecting internal trade secrets is essential to maintaining a competitive edge and safeguarding proprietary information from competitors, cybercriminals, and corporate espionage. Whatever the information (a new product design, marketing strategy, financial data, or research and development (R&D) plans) keeping confidential information secure ensures that a company's intellectual property remains protected. Businesses face increasing threats from insider leaks, cyber intrusions, and corporate espionage. Competitors, foreign entities, or even disgruntled employees may attempt to steal sensitive information for financial or strategic gain. Embodiments described herein provide secure communication spaces.

For individuals or organizations that need to operate securely without the risk of interception, maintaining privacy and protecting communications is essential. Whether it's a high-profile executive, journalist, whistleblower, cybersecurity professional, or government contractor, ensuring that conversations, data, and activities remain confidential can prevent unauthorized access, espionage, or surveillance.

Although the shielded enclosure panel and systems are shown and described herein with certain components and functionality, other embodiments of the shielded enclosure door apparatus and systems may include fewer or more components to implement less or more functionality.

Some embodiments of the shielded enclosure panel are designed to be used on the inner box. Some embodiments of the shielded enclosure panel are designed to be used on the outer box. The outer box may be a shipping container or ISO container and may use traditional doors or embodiments described herein.

The following includes description of the overall shielded enclosure to help understand the system into which embodiments of a shielded enclosure panel is utilized. In some embodiments, the inner box may be constructed so as to be inserted into the outer box or shipping container with various components between the outer box and the inner box. In some embodiments, the inner box will rest on the floor of the outer box with an insulating material between the inner box and the floor of the outer box. In some embodiments, the insulating material is a sub-floor that separates the inner box and the outer box. In some embodiments, the insulating material is a non-metallic board that sits between the inner box and the floor of the outer box. The insulating material is configured to separate the inner box from the outer box mechanically and electrically such that any signal energized on the inner box is not transferred to the outer box and amplified.

While the base of the inner box is configured to rest on the sub-floor that is between the inner box and the outer box, the remaining sides of the inner box are separated from the outer box by various intermediary components described below. Throughout this description, the phrase “remaining sides” will refer to all sides except for the bottom side (also referred to as floor) of the inner box. These intermediary components are illustrative and may or may not be present in all embodiments and implementations of the invention. In some embodiments, there is an air gap between the outer box and the inner box. In some embodiments, the air gap is configured to function as a dielectric or insulating area that separates the inner box from the outer box on the remaining sides mechanically and electrically such that any signal energized on the inner box is not transferred to the outer box and/or amplified on the outer box. As explained more fully below, the air gap may additionally allow for the inner box and the outer box to be separately grounded.

In some embodiments, there are additional components between the inner box and the outer box. In many embodiments, the outer box is a metallic material. In some embodiments, the outer box has a substance or coating on the interior surface of the outer box. Although referred to as a coating herein, in some embodiments, the coating may be a non-metallic board that ensures that no metal-to-metal contact occurs with the interior surface of the outer box and other components (most especially the inner box). In some embodiments, the coating is merely a non-metallic substance. In some embodiments, the coating could be paint. The coating is configured to restrict metal-to-metal contact such that the various components of the apparatus do not amplify errant signals originating within the interior workspace.

In some embodiments, the shielded enclosure apparatus and systems include a metallic mesh abutting the coating. The metallic mesh, for example, may include copper, brass nickel, aluminum, steel, stainless steel, or hardened steel. In some embodiments, the metallic mesh may surround and/or enclose the remaining sides of the inner box with the air gap between the copper mesh and the exterior surface of the inner box.

Returning to the inner box, the inner box may be, in some embodiments, comprised of various subcomponents. In an illustrative embodiment, the inner box is comprised of a plurality of panels and posts that are coupled together (such as continuously welded together), where each panel or post comprises an inner subpanel that forms the interior surface of the inner box and an outer subpanel that forms the exterior surface of the inner box with a gap between the inner subpanel and the outer subpanel. House in the gap between the inner subpanel and the outer subpanel is acoustic insulation. In some embodiments, the acoustic insulation is insulating material that is configured to dampen or restrict acoustic vibrations from exiting the interior workspace to the surrounding environment.

To illustrate more clearly the order and relative position of the various components, an example embodiment is described in this paragraph. In the illustrative embodiment, the interior workspace is separated from the surrounding environment by an inner subpanel and, in succession, acoustic insulation, an outer subpanel, an air gap, copper mesh, coating, and outer box. In some embodiments, this is a shielded enclosure panel. In some embodiments, the shielded enclosure panel includes a first metal sheet and a second metal sheet coupled to the first metal sheet and enclosing a cavity. In some embodiments, the shielded enclosure panel includes a first EMI absorber on an inside surface of the first metal sheet and a second EMI absorber on an inside surface of the second metal sheet. In some embodiments, the shielded enclosure panel includes a waveguide positioned between the first and second EMI absorbers and acoustic insulation positioned between the waveguide and each EMI absorber and wherein the shielded enclosure panel produces an electromagnetic transmission attenuation between 9 kHz and 40 gHz.

In some embodiments, the shielded enclosure panel includes a panel box including a first metal sheet forming a first side of the panel box and a second metal sheet forming a second side of the panel box with a gap therebetween. In some embodiments, the shielded enclosure panel includes a first EMI absorber on an inside surface of the first metal sheet and a second EMI absorber on an inside surface of the second metal sheet. In some embodiments, the shielded enclosure panel includes a waveguide positioned between the first and second EMI absorbers and acoustic insulation positioned between the waveguide and each EMI absorber.

The various components and features described herein work together to protect from electromagnetic transmission interception that emanates from or is produced within the inner box. Electromagnetic transmission interception occurs when adversaries use specialized equipment to capture electromagnetic transmissions emitted by electronic devices, including computers, phones, and communication systems. This type of surveillance can lead to severe security breaches, making it essential to implement protective measures. Embodiments described herein help reduce or eliminate electromagnetic transmission interception. In some cases, electromagnetic transmission protection (or electromagnetic transmission attenuation) is provided between 9 kHz and 40 GHZ, 9 MHz and 40 GHz, or 9 MHz and 20 GHz.

The various components and features described herein work together to protect against sound transmission and other acoustics. Sound Transmission Control (STC) refers to the methods used to prevent sound from traveling outside a designated area, reducing the risk of eavesdropping or unauthorized listening. In some cases, the STC rating is greater than about 35, 40, 45, 50, 55, 60, 65, etc.

In some embodiments, the shielded enclosure panel includes a first metal sheet and a second metal sheet coupled to the first metal sheet and enclosing a cavity. The shielded enclosure panel includes a first EMI absorber on an inside surface of the first metal sheet and a second EMI absorber on an inside surface of the second metal sheet. In some embodiments, the shielded enclosure panel includes a waveguide positioned between the first and second EMI absorbers and acoustic insulation positioned between the waveguide and each EMI absorber. The panels in many embodiments must be able to achieve the same sound and electromagnetic transmission interception as the overall system. That is, the panel itself is designed to help reduce or eliminate electromagnetic transmission interception. In some cases, electromagnetic transmission protection (or electromagnetic transmission attenuation) is provided between 9 kHz and 40 GHz, 9 MHz and 40 GHz, or 9 MHz and 20 GHz. Additionally, the panel itself is designed to protect against sound transmission and other acoustics. In some cases, the STC rating of greater than about 40 or above or about 55 or above. This may be accomplished in some cases through the thickness of the shielded enclosure panel.

In some embodiments, the first metal sheet and the second metal sheets are welded closed to enclose the cavity such as, for example, around a periphery of the first metal sheet and a periphery of the second metal sheet. In some embodiments, the cavity is fully sealed. In some embodiments, the EMI absorber is a flat absorber and comprises ferrite. In some embodiments, the shielded enclosure door produces an electromagnetic transmission attenuation between 9 kHz and 40 gHz and/or an STC rating of greater than about 40 or above or about 55 or above. In some embodiments, there is an airgap in the waveguide cells. In some embodiments, the acoustic insulation is mineral wool. In some embodiments, the waveguide is a honeycomb pattern having a cell size with at least a first dimension of between 1/16″ to 1″ and a second dimension of between ½ to 3″ such as, for example, a first dimension of ⅛″ and a second dimension of 1″. In some embodiments, the first and second metal sheet are 304 stainless steel. In some embodiments, the first and second metal sheet are 14-gauge steel.

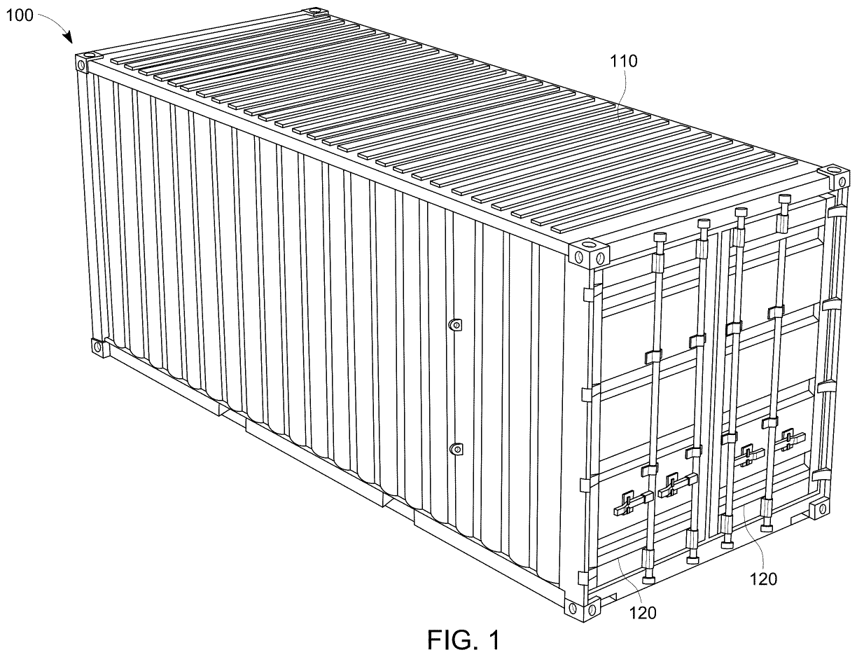

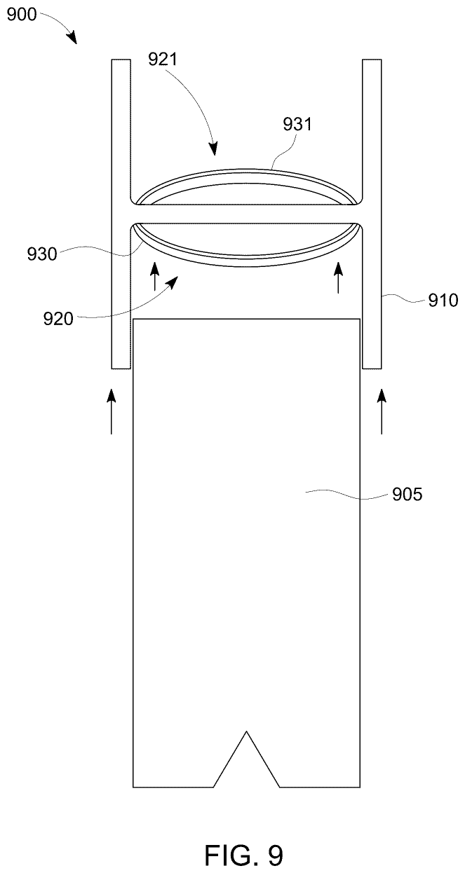

FIGS. 1-8 depict the overall shielded enclosure system and are shown for context and have features that work in conjunction with the shielded enclosure panel which is shown and described in more detail in FIGS. 9-11.

FIG. 1 depicts a perspective view of the exterior of the shielded enclosure apparatus 100 according to one or more embodiments of the invention. Although the shielded enclosure apparatus 100 is shown and described with certain components and functionality, other embodiments of the shielded enclosure apparatus 100 may include fewer or more components to implement less or more functionality.

In the illustrated embodiment, the shielded enclosure apparatus 100 appears from the outside as an ISO container. An ISO container, also known as an intermodal or shipping container, is a standardized metal box used for transporting goods across different modes of transport, such as ships, trucks, and trains, without needing to unload and reload the cargo. These containers are built to specific dimensions and strength standards set by the International Organization for Standardization (ISO) to ensure efficiency and safety in shipping. In the illustrated embodiment, the ISO container functions as a six-sided box that functions as the outer box 110 of the shielded enclosure apparatus 100. In the illustrated embodiment, the outer box 110 is a six-sided welded enclosure with a single point of access through outer box doors 120.

Although the shielded enclosure apparatus 100 is shown as a six-sided rectangular prism similar to a shipping container, the shielded enclosure apparatus 100 may be constructed in different shapes and sizes which are not shown only for the sake of brevity. In some embodiments, the outer box 110 is a metallic box sealed and impenetrable on all sides but the single access side. In the illustrated embodiment, the outer box 110 is made of 14 gauge steel that is welded to create an enclosure. The outer box 110, in conjunction with some of the other features described herein work together to provide a shielded enclosure that blocks, attenuates, or reduces radio frequency signals and other electromagnetic transmissions as well as vibrational waves such as sound waves, acoustic waves or audio waves.

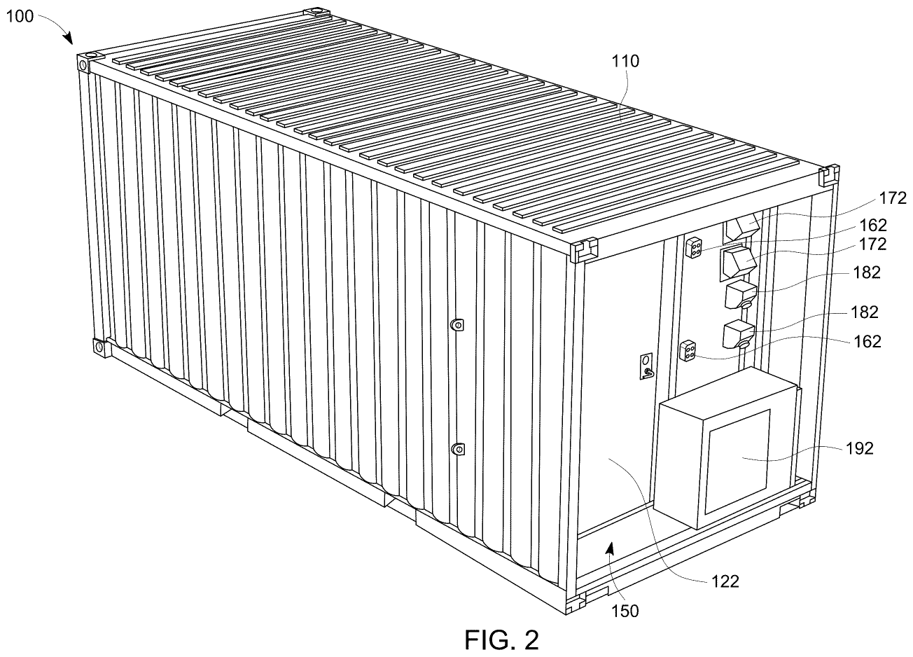

FIG. 2 is a perspective cutaway view of a shielded enclosure system showing a vestibule area just inside the outer box doors 120 according to some embodiments. The illustrated embodiment shows a vestibule 150 (sometimes referred to as a vestibule area, outer entrance area, outer access point area). The vestibule 150 is a small area between the outer box 110 and the inner box (more fully described in subsequent figures) that may be used to house equipment needed for the shielded enclosure apparatus 100. The equipment described herein may be present in some but not all embodiments.

In the illustrated embodiment, the vestibule serves as the only access point to the interior workspace for a few primary sets of equipment: communications, power, heat, and air. In the illustrated embodiment, a heat exchanger 192 is shown in the vestibule 150. The heat exchanger 192 may serve as a system to transfer heat and maintain a suitable temperature within the interior workspace. As has been discussed, the shielded enclosure apparatus 100 may be transportable or mobile and may be moved to different locations and in vastly different climates and may need to maintain a suitable temperature within the interior workspace to preserve and maintain equipment.

The illustrated embodiment also shows air exchanger ports 172 which may serve to maintain fresh air within the interior workspace of the shielded enclosure apparatus. The illustrated embodiment also shows power ports 182 that may be used to port power into the interior workspace of the shielded enclosure apparatus. The illustrated embodiment further shows receptacles 162 which may be used to pass communication cables or other communications equipment into or out of the interior workspace of the shielded enclosure apparatus.

The illustrated embodiment also shows an outer door 122 (also called herein outer door of the inner box, outer door of the first shield line, or interior box outer door). The outer door 122 acts as an access point to the interior workspace and may include features similar to those shown on the remaining sides of the inner box.

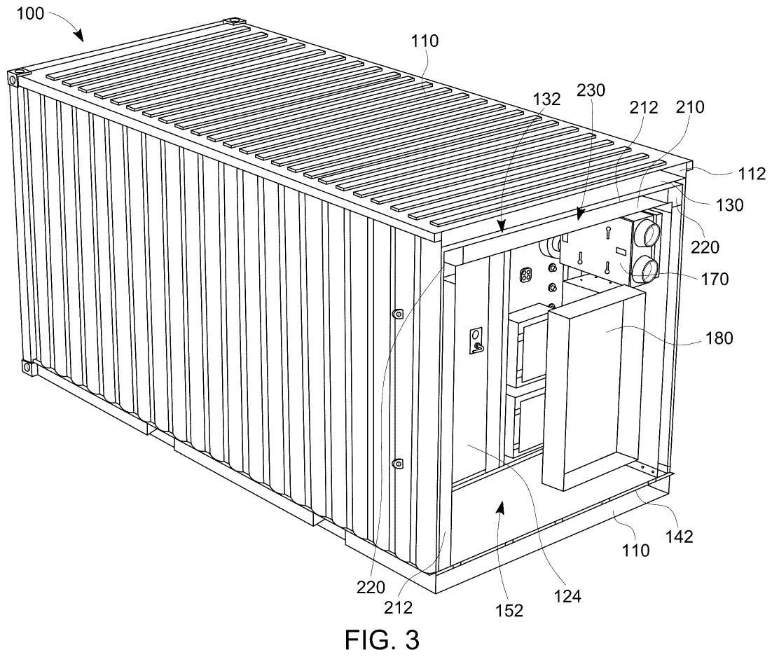

FIG. 3 is a perspective cutaway view of a shielded enclosure system showing the area within the outer door according to some embodiments. The illustrated embodiment shows a separate technical boundary 152 (sometimes referred to as a technical area, inner entrance area, inner access point area. The technical boundary 152 is a small area between the outer door 122 and an inner door 124 of the inner box that may be used to house more equipment needed for the shielded enclosure apparatus 100. The equipment described herein may be present in some but not all embodiments.

In the illustrated embodiment, the inner entrance area serves as the only access point to the interior workspace for a few primary sets of equipment. The illustrated embodiment also shows an inner door 124 (also called herein inner door of the inner box, inner door of the first shield line, or interior box inner door). The inner door 124 acts as an access point to the interior workspace and may include features similar to those shown on the remaining sides of the inner box. Because the overall access to the interior workspace may serve as a potential spot for eavesdropping access, the multi-layered entrance has been shown with outer container doors 120, followed by outer door 122, and further followed by inner door 124 which are used to access the interior workspace. The inner door 124 and the outer door 122 work as a double door configuration with a space between to reduce, dampen, or eliminate leakage of the sound waves from the interior workspace to the exterior of the shielded enclosure apparatus 100.

The separate technical boundary 152 may not be completely shielded for sound waves as it is outside the inner door but is shielded on all six sides from rf signals. The illustrated embodiment also shows an air exchanger 170 which may serve to maintain fresh air within the interior workspace of the shielded enclosure apparatus. The air exchanger 170 is positioned to mix fresh air with return air, improving conditioning efficiency within the interior workspace. The air exchanger 170 may be the only means of introducing fresh air into the interior workspace. In some embodiments, the air exchanger 170 employs silencers and/or waveguides (such as honeycomb waveguides) to prevent electromagnetic transmission escape or intrusion. The silencers and/or waveguides, for example, may include a honeycomb pattern. The silencers and/or waveguides, for example, may be made from brass, aluminum, steel, nickel, stainless steel, hardened steel, or any other metal. The honeycomb pattern, for example, may have a cell size with at least a first dimension of between 1/16″ to 1″ and second dimension of between ½ to 3″ such as, for example, a first dimension of ⅛″ and a second dimension of 1″; although, various other sizes may be used. Alternatively, other patterns could be, such as, for example, a circular, triangular, rectangular, or wavy pattern.

The illustrated embodiment also shows a power filter 180 that may be used to filter and supply power into the interior workspace of the shielded enclosure apparatus. All power supplying the shielded enclosure apparatus 100 is routed through the power filter 180, which is specifically rated for the shielded enclosure apparatus's power requirements. The illustrated embodiment further shows receptacles which may be used to pass communication cables or other communications equipment into or out of the interior workspace of the shielded enclosure apparatus. The power filter, for example, may include an inline, low pass power filter. The power filter, for example, may include only passive components. The power filter, for example, may strip off the noise by flipping the polarity.

In the cutaway view of the shielded enclosure apparatus 100, a cross section of the inner box and the outer box 110 and various components between is shown. The inner box (also called herein an interior box, interior metallic box, inner shield line, shielded interior, or shield line interior box) is separated from the outer box 110 by an air gap 132 and other components. The air gap 132 exists between the inner box and the outer box and allows for the separate grounding of the two boxes. That is, the inner box may be grounded to a separate location from the outer box. This break keeps dielectric separation between the two boxes and reduces or eliminates transfer of electromagnetic transmission signals or sound waves from the inner box to the outer box.

In the illustrated embodiment, the inner box is a metal welded enclosure made up of panels and posts 220 (sometimes referred to as a steel structural frame or structural frame) that arc continuously welded to provide a sealed enclosure. The panels comprise an inner panel 210 (also referred to as a metal sheet) and an outer panel 212 (also referred to as a second metal sheet) that are separated from each other by acoustic insulation 230. The inner and outer panels may be secured together but have the acoustic insulation 230 housed between them.

In the illustrated embodiment, the shielded interior is a box constructed from four-inch depth panels of 14-gauge steel (for the outer panel 212 and the inner panel 210) filled with acoustic insulation between. These panels may be made from other gauges of steel such as, for example, 10-gauge, 12-gauge, 16-gauge, 18-gauge, etc. Alternatively, these panels may be made from aluminum of any of the disclosed or other gauges. In some embodiments, the acoustic insulation 230 may include mineral wool or a metallic insulation material. As explained previously, the inner box is non-metallically separated from the outer box or ISO container. To achieve this separation, the interior of the outer box 110 is coated with a non-metallic coating 112 to prevent any metal-to-metal contact. The non-metallic coating 112 is three millimeters thick and serves as a barrier to eliminate bare metal exposure on the interior surface of the outer box 110. In some embodiments, the non-metallic coating 112 may be a non-metallic paint. In other embodiments, any non-metallic coating could be used for the purpose of preventing metal-to-metal contact.

Referring to the inner box, this shielded box acts as the primary shield line (or first shield line) and is independently grounded from the exterior or outer box. In the illustrated embodiment, the panels are set in place and continuously welded on all sides to the steel structural frame. In some embodiments, the steel structural frame may be 8-gauge steel, 10-gauge steel, 12-gauge steel, 14-gauge steel, 16-gauge steel, etc. After assembly of the inner box, the entire inner box may be slid into the outer box or ISO container using guide rails, ensuring perfect alignment with the exterior walls and roof and ensuring an air gap 132 between the inner and outer box.

Referring now to the floor or bottom of the inner and outer boxes, it is also designed for non-metallic separation between the two boxes. In the illustrated embodiment, there is a non-metallic base floor 142 between the outer box 110 and the metal bottom of the inner box. The non-metallic base floor prevents any metal-to-metal contact between the floors of the two boxes. In some embodiments, the non-metallic base floor is made of wood. In an embodiment, the non-metallic base floor is a plywood base followed by a layer of steel (e.g., 8-gauge steel, 10-gauge steel, 12-gauge steel, 14-gauge steel, 16-gauge steel, etc.) for the floor of the inner box. Structurally, the sequence from bottom to top on the floor includes the outer box 110, a layer of wood (the non-metallic base floor 142), and the floor of the inner box (a layer of steel).

In some embodiments, there is an additional layer between the inner box and the outer box. In the illustrated embodiment, there is a mesh 130 just inside of the non-metallic coating 112 on the interior surface of the outer box 110. In some embodiments, the metallic mesh is a copper mesh layered against the coating (the coating separating the metal surface of the outer box and the mesh 130. The metallic mesh addresses any residual reflective energy from the interior box. The shielded enclosure apparatus 100 uses the double shield line so that any residual reflective energy or sound that might escape the inner box (or first shield line) may be attenuated, grounded, or blocked by the outer box (or second shield line). This allows for electromagnetic transmission rated and STC rated shielded enclosure with the inner box and the outer box separately grounded and working together to control electromagnetic transmissions and acoustics and reduce or eliminate any potential eavesdropping within the shielded enclosure apparatus 100. In some cases, the shielded enclosure apparatus 100 can shield frequencies between 9 MHz and 20, 9 kHz and 40 GHz, 9 MHz and 40 GHz. The shielded enclosure apparatus 100 may further have an STC rating above 40 or above 55, and/or audio control between 100 and 120 decibels of sound.

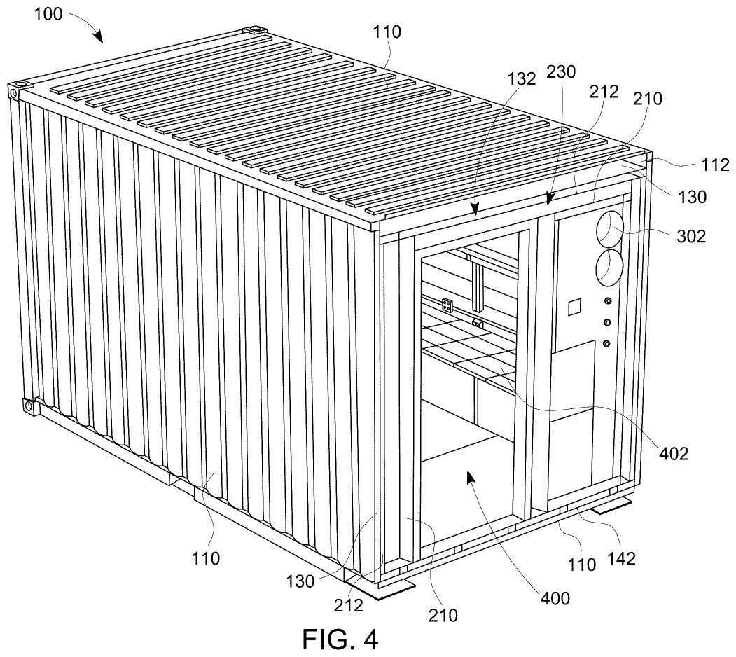

FIG. 4 is a perspective cutaway view of a shielded enclosure system showing a portion of the interior workspace according to some embodiments. The cutaway view eliminates the inner door 124 and shows the interior workspace 400 (alternatively called a work area, production space, or protected area) that the shielded enclosure apparatus is protecting from the surrounding environment.

The illustrated embodiment further shows various ports 302 that allow for the ingress/egress of the equipment/systems described previously including the communications, power, heat, and air systems. Within the interior workspace 400, there may be additional equipment, cabinetwork, or amenities as needed. In the illustrated embodiment, a desk space 402 is shown where a user can set up within the interior workspace 400.

As before, in this cutaway view of the shielded enclosure apparatus 100, a cross section of the inner box and the outer box 110 and various components between is shown. The inner box is separated from the outer box 110 by an air gap 132 and other components. The air gap 132 exists between the inner box and the outer box and allows for the separate grounding of the two boxes. As before, the inner box is a metal welded enclosure made up of panels secured to the structural frame that are continuously welded. The panels comprise an inner metal sheet and an outer metal sheet that are separated from each other by acoustic insulation 230. The inner box is non-metallically separated from the outer box. The interior of the outer box 110 is coated with a non-metallic coating 112 to prevent any metal-to-metal contact. The non-metallic coating 112 can serve as a barrier to eliminate bare metal exposure on the interior surface of the outer box 110.

Referring to the inner box, this shielded box acts as the primary shield line (or first shield line) and is independently grounded from the exterior or outer box. The grounding allows for grounding of reflective energy and signals on the inner box to be grounded in a separate location from the outer box. Separate grounding allows for separate attenuation and makes it so the outer box does not amplify or extend any signal that makes it to the inner box. The floors are separated by the non-metallic base floor 142 between the outer box 110 and the metal bottom of the inner box. The non-metallic base floor prevents any metal-to-metal contact between the floors of the two boxes and supports the separate grounding of the inner box from the outer box.

In the illustrated embodiment, the mesh 130 just inside of the non-metallic coating 112 on the interior surface of the outer box 110 is present and can further address any residual reflective energy from the interior box. The shielded enclosure apparatus 100 uses double shield lines so that any residual reflective energy or sound that might escape the inner box (or first shield line) may be attenuated, grounded, or blocked by the outer box (or second shield line).

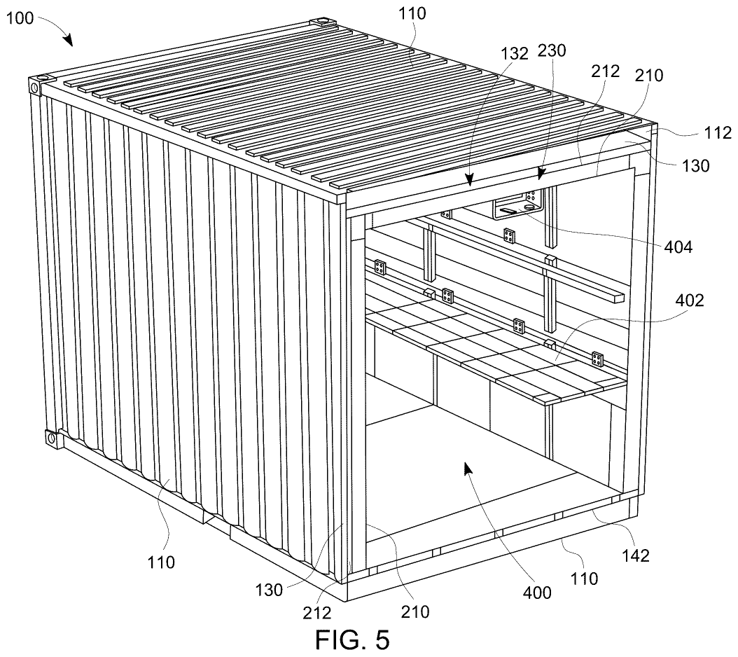

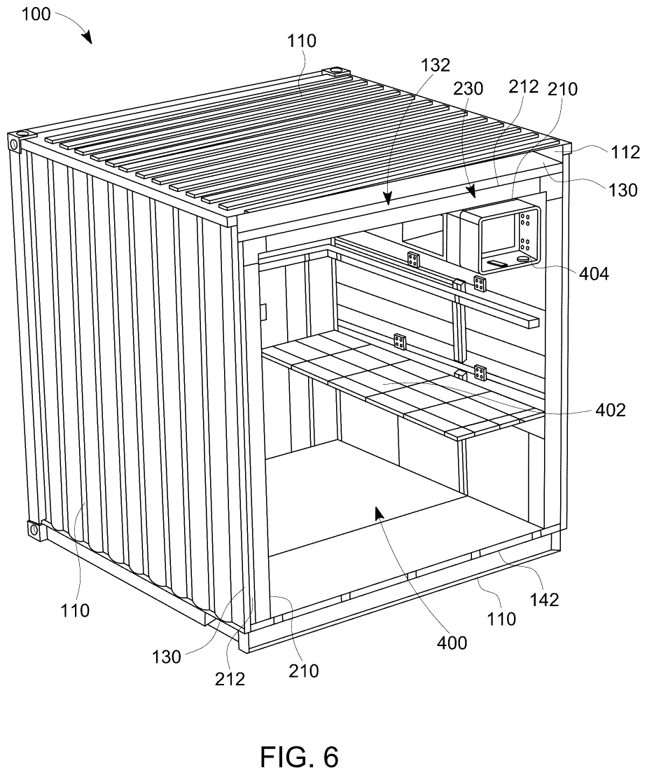

FIG. 5 is a perspective cutaway view of a shielded enclosure system showing a portion of the interior workspace according to some embodiments. The cutaway view eliminates one side of the inner box and shows the interior workspace 400 that the shielded enclosure apparatus is protecting from the surrounding environment. FIG. 6 shows a perspective cutaway view of the shielded enclosure system deeper into the interior workspace.

The illustrated embodiment further shows a desk space 402 is shown where a user can set up within the interior workspace 400 and cabinets 404 that can be used to house electronic equipment or other equipment as needed. The cabinets 404 are separated from the interior surface of the inner box so as to not attenuate any signal from the electronic equipment in the cabinet to the inner box.

As before, in this cutaway view of the shielded enclosure apparatus 100, a cross section of the inner box and the outer box 110 and various components between is shown. The inner box is separated from the outer box 110 by an air gap 132 and other components. The air gap 132 exists between the inner box and the outer box and allows for the separate grounding of the two boxes. As before, the inner box is a metal welded enclosure made up of panels secured to the structural frame that are continuously welded. The panels comprise an inner metal sheet and an outer metal sheet that are separated from each other by acoustic insulation 230. The inner box is non-metallically separated from the outer box. The interior of the outer box 110 is coated with a non-metallic coating 112 to prevent any metal-to-metal contact. The non-metallic coating 112 serves as a barrier to eliminate bare metal exposure on the interior surface of the outer box 110.

Referring to the inner box, this shielded box acts as the primary shield line (or first shield line) and is independently grounded from the exterior or outer box. The grounding allows for grounding of reflective energy and signals on the inner box to be grounded in a separate location from the outer box. Separate grounding allows for separate attenuation and makes it so the outer box does not amplify or extend any signal that makes it to the inner box. The floors are separated by the non-metallic base floor 142 between the outer box 110 and the metal bottom of the inner box. The non-metallic base floor prevents any metal-to-metal contact between the floors of the two boxes and supports the separate grounding of the inner box from the outer box.

In the illustrated embodiment, the metallic mesh 130 just inside of the non-metallic coating 112 on the interior surface of the outer box 110 is present and can further address any residual reflective energy from the interior box. The shielded enclosure apparatus 100 uses double shield lines so that any residual reflective energy or sound that might escape the inner box (or first shield line) may be attenuated, grounded, or blocked by the outer box (or second shield line).

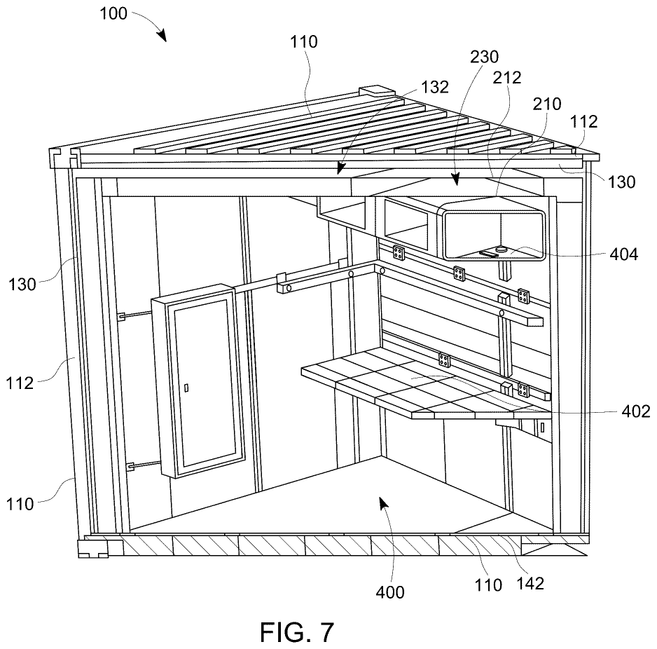

FIG. 7 is a perspective cutaway view of a shielded enclosure system with the cutaway at an angle. The illustrated embodiment further shows a desk space 402 is shown where a user can set up within the interior workspace 400 and cabinets 404 that can be used to house electronic equipment or other equipment as needed. The cabinets 404 are separated from the interior surface of the inner box so as to not attenuate any signal from the electronic equipment in the cabinet to the inner box.

As before, in this cutaway view of the shielded enclosure apparatus 100, a cross section of the inner box and the outer box 110 and various components between is shown. The inner box is separated from the outer box 110 by an air gap 132 and other components. The air gap 132 exists between the inner box and the outer box and allows for the separate grounding of the two boxes. As before, the inner box is a metal welded enclosure made up of panels secured to the structural frame that are continuously welded. The panels comprise an inner metal sheet and an outer metal sheet that are separated from each other by acoustic insulation 230. The inner box is non-metallically separated from the outer box. The interior of the outer box 110 is coated with a non-metallic coating 112 to prevent any metal-to-metal contact. The non-metallic coating 112 serves as a barrier to eliminate bare metal exposure on the interior surface of the outer box 110.

Referring to the inner box, this shielded box acts as the primary shield line (or first shield line) and is independently grounded from the exterior or outer box. The grounding allows for grounding of reflective energy and signals on the inner box to be grounded in a separate location from the outer box. Separate grounding allows for separate attenuation and makes it so the outer box does not amplify or extend any signal that makes it to the inner box. The floors are separated by the non-metallic base floor 142 between the outer box 110 and the metal bottom of the inner box. The non-metallic base floor prevents any metal-to-metal contact between the floors of the two boxes and supports the separate grounding of the inner box from the outer box.

In the illustrated embodiment, the mesh 130 just inside of the non-metallic coating 112 on the interior surface of the outer box 110 is present and can further address any residual reflective energy from the interior box. The shielded enclosure apparatus 100 uses double shield lines so that any residual reflective energy or sound that might escape the inner box (or first shield line) may be attenuated, grounded, or blocked by the outer box (or second shield line).

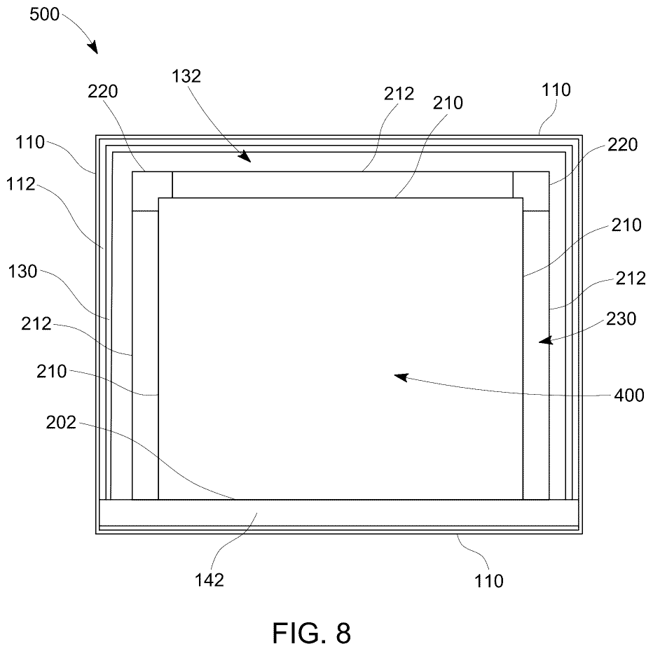

FIG. 8 is a schematic diagram 500 of a cross section of a shielded enclosure system according to some embodiments. The schematic diagram shows the general configuration and should not be used to interpret the general sizes of the different components and layers. The shielded enclosure apparatus and system is used separate the interior workspace 400 (alternatively called a work area, production space, or protected area) from a surrounding environment and further prevent eavesdropping from outside the shielded enclosure apparatus. The shielded enclosure apparatus includes generally two boxes, an outer box 110 and an inner box that work together to separate and enclose the interior workspace 400 from the surrounding environment. The outer box 110 surrounds and encloses the inner box. The outer box 110 includes at least one door or area of ingress/egress to access the inner box. The inner box surrounds and encloses the interior workspace 400. The inner box includes at least one door or area of ingress/egress to access the interior workspace 400.

The interior workspace 400 may be used for any work or communications that require isolation from a surrounding area that may be subject to sophisticated surveillance technologies. Any type of work may be conducted within the interior workspace 400. The interior workspace 400 may include computer terminals or other types of electronic devices upon which a user can conduct work that is intended to be kept secret or isolated from the surrounding environment.

In some embodiments of the shielded enclosure apparatus and systems, the apparatus is portable or mobile. The outer box 110 may be a shipping container or ISO container which allows for the shielded enclosure apparatus to be transported to different locations in a manner similar to any traditional shipping container.

In some embodiments, the inner box may be constructed so as to be inserted into the outer box with various components between the outer box and the inner box. In the illustrated embodiment, the inner box rests on the floor of the outer box with an insulating material (or non-metallic base floor 142) between the inner box and the floor of the outer box. In some embodiments, the insulating material is a sub-floor that separates the inner box and the outer box. In some embodiments, the insulating material is a non-metallic board that sits between the inner box and the floor of the outer box. The insulating material is configured to separate the inner box from the outer box mechanically and electrically such that any signal energized on the inner box is not transferred to the outer box and amplified. In some embodiments, the base floor is a wood floor or plywood.

While the base of the inner box is configured to rest on the sub-floor that is between the inner box and the outer box 110, the remaining sides of the inner box are separated from the outer box 110 by various intermediary components. “Remaining sides” will refer to all sides except for the bottom side (also referred to as floor) of the inner box. In some embodiments, there is an air gap 132 between the outer box 110 and the inner box. In some embodiments, the air gap 132 is configured to function as a dielectric or insulating area that separates the inner box from the outer box 110 on the remaining sides mechanically and electrically such that any signal energized on the inner box is not transferred to the outer box 110 and/or amplified on the outer box 110. The air gap 132 may additionally allow for the inner box and the outer box 110 to be separately grounded.

In the illustrated embodiment, the outer box 110 has a substance or coating non-metallic 112 on the interior surface of the outer box 110. In some embodiments, the coating may be a non-metallic board that ensures that no metal-to-metal contact occurs with the interior surface of the outer box 110 and other components (most especially the inner box). In some embodiments, the non-metallic coating 112 is merely a non-metallic substance. In some embodiments, the non-metallic coating 112 can be a non-metallic paint. The non-metallic coating 112 is configured to restrict metal-to-metal contact such that the various components of the apparatus do not amplify errant signals originating within the interior workspace 400.

In some embodiments, the shielded enclosure apparatus 100 include a mesh 130 (e.g., a metal mesh, a copper mesh, or a brass mesh) abutting the coating. In some embodiments, the mesh 130 further surrounds and encloses the remaining sides of the inner box with the air gap between the copper mesh and the exterior surface of the inner box. In some embodiments, the mesh 130 surrounds all sides of the inner box.

The inner box may be, in some embodiments, comprised of various subcomponents. In the illustrated embodiment, the inner box is comprised of a plurality of panels 210, 212 and structural posts 220 that are coupled together. Housed in the gap between the inner panel or subpanel 210 and the outer panel or subpanel 212 is acoustic insulation 230. In some embodiments, the acoustic insulation 230 is insulating material that is configured to dampen or restrict acoustic vibrations from exiting the interior workspace to the surrounding environment.

In an illustrative embodiment (as shown in this figure), the interior workspace 400 is separated from the surrounding environment by an inner panel 210 and, in succession, acoustic insulation 230, an outer panel 212, an air gap 132, a mesh 130, a non-metallic coating 112, and an outer box 110.

The various components and features described herein work together to protect from radio frequency (RF) interception. Electromagnetic transmission interception occurs when adversaries use specialized equipment to capture electromagnetic transmissions emitted by electronic devices, including computers, phones, and communication systems. This type of surveillance can lead to severe security breaches, making it essential to implement protective measures. Embodiments described herein help reduce or eliminate radio frequency (RF) interception. In some cases, electromagnetic transmission protection is provided between 9 MHz and 20 GHz.

The various components and features described herein work together to protect against sound transmission and other acoustics. Sound Transmission Control (STC) refers to the methods used to prevent sound from traveling outside a designated arca, reducing the risk of eavesdropping or unauthorized listening. In some cases, the STC rating may be about 40 or above, or about 55 or above.

FIG. 9 is a schematic diagram of cross section of panel 905 and I-beam 910 construction arrangement 900 according to some embodiments. A shielded enclosure apparatus 100, for example, may be constructed from a plurality of panels 905 disposed between I-beams 910. Each panel 905, for example, may include any panel disclosed in this document.

A panel 905 may be coupled with I-beam 910 by sliding an end of the panel 905 into a gap 920 of the I-beam 910. A tension member 930 may be disposed within the gap 920. The tension member 930, for example, may comprise beryllium copper. The tension member 930, for example, may be compressed wen the panel 905 is slide into the gap 920. An I-beam 910 may be placed on opposite sides of a panel 920 and provide compression and/or tension and/or provide grounding contact between the I-beam 910 and the panel 905. The tension member 930, for example, may comprise beryllium copper. The I-beam 910, for example, may comprise 8, 10, or 12 gauge steel.

The width of the gap 920 may be 0.5, 0.75%, 1%, 1.25%, 1.5%, etc. greater than the width of the panel 905.

A second panel may be coupled with the I-beam by sliding an end of the second panel into the gap 921 of the I-beam 910. A second tension member 931 may be disposed within the gap 921. The second pap 921 may have the same properties as the gap 920. The second tension member 931 may have the same properties as the tension member 930.

The interior workspace is accessible via doors or areas of ingress/egress on the outer box and the inner box. In some embodiments, the outer box includes at least one door or area of ingress/egress for a user. In some embodiments, the area of ingress/egress is an outer box door (also referred to as a container door or second shield line exterior door).

In some embodiments, the inner box includes at least one door or area of ingress/egress for a user. In some embodiments, the inner box includes at least two doors or areas of ingress/egress for a user, including an outer door and an inner door. In some embodiments, there is a vestibule or space between the inner door and the outer door. In some embodiments, the vestibule can be a mechanical area or equipment area. Housed within the vestibule can be various systems including a power box that provides power to the interior workspace, an air exchanger that provides fresh air to the interior workspace, and other electrical equipment.

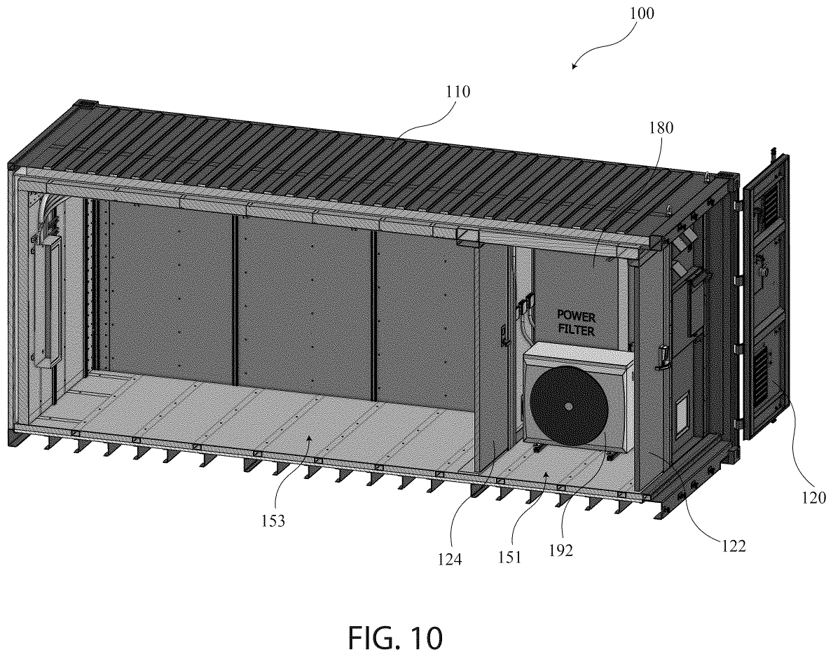

FIG. 10 is a side view of a cutaway of a shielded enclosure panel according to some embodiments. Although the shielded enclosure panel 700 is shown and described with certain components and functionality, other embodiments of the shielded enclosure panel 700 may include fewer or more components to implement less or more functionality. Additionally, although this description is of a shielded enclosure panel 700, it is equally applicable to the description of the inner panel 210 and the outer panel 212 described above. The additional components described within shielded enclosure panel 700 may be applied to the above components in the overall shielded enclosure. All features described in conjunction with the following figures may be applied to other panels of the shielded enclosure system 100.

The shielded enclosure panel 700 includes generally a first metal sheet 722 (could be alternatively described as the inner panel 210) and a second metal sheet 724 (could be alternatively described as the outer panel 212) with a cavity between the first and second metal sheets 722, 724. In some embodiments, the cavity may have an air gap. In some embodiments, the cavity is filled with other components. The cavity exists between the first metal sheet 722 and the second metal sheet 724 and is closed off by end caps 726. That is, the first metal sheet 722 and the second metal sheet 724 along with the end caps 726 form a box shape (sometimes referred to as a panel box). In some embodiments, the first and second metal sheets 722, 724 are welded to the end caps 726 to form the panel box and to enclose the cavity. In some embodiments, the cavity is fully sealed. Because of this, the shielded enclosure panel 700 like the overall system uses components sealed within to attenuate electromagnetic transmissions and dampen or eliminate sound getting through. This allows for electromagnetic transmission rated and STC rated shielded enclosure panels to control electromagnetic transmissions and acoustics and reduce or eliminate any potential eavesdropping within the shielded enclosure apparatus 100. In some cases, the shielded enclosure panel 700 can shield frequencies between 9 MHz and 20, 9 kHz and 40 GHz, 9 MHz and 40 GHz. The shielded enclosure panel 700 may further have an STC rating of greater than about 40 or above or about 55 or above, and/or audio control between 100 and 120 decibels of sound.

In some embodiments, the metal sheets 722, 724 and end caps 726 may be 14-gauge steel and are filled with various components between. These metal sheets and end caps may be made from other gauges of steel such as, for example, 10-gauge, 12-gauge, 16-gauge, 18-gauge, etc. Alternatively, these metal sheets and end caps may be made from aluminum of any of the disclosed or other gauges or may be made of stainless steel 304 or other similar materials.

In some embodiments, the shield enclosure panel 700 includes EMI absorbers. EMI absorbers are specialized materials designed to reduce or eliminate unwanted electromagnetic transmission energy propagation outside the interior workspace. They may work by converting incident electromagnetic transmission waves including electromagnetic transmissions into heat, effectively “absorbing” the energy rather than allowing it to reflect, transmit outside, or interfere with other equipment or communications. EMI absorbers come in various forms, including sheets, foams, paints, and coatings, and they are typically composed of materials with magnetic or dielectric properties, such as ferrites or carbon-loaded polymers. In many embodiments, the EMI absorbers are flat sheets within the shielded enclosure panel 700. In some embodiments, the EMI absorbers are ferrite sheets. Other types of materials are contemplated that may shield the frequencies discussed herein.

In some embodiments, the shielded enclosure panel 700 includes a first EMI absorber 732 on an inside surface of the first metal sheet 722. In some embodiments, the shielded enclosure panel 700 includes a second EMI absorber 734 on an inside surface of the first metal sheet 724. The two EMI absorbers can work together to attenuate any electromagnetic transmissions coming from inside the interior workspace.

In some embodiments, the shielded enclosure panel 700 is filled with acoustic insulation 750. In some embodiments, the acoustic insulation 750 may include mineral wool or a metallic insulation material and may be similar to other acoustic insulation described herein. In some embodiments, the shielded enclosure panel 700 employs silencers and/or waveguides 760 (such as honeycomb waveguides) to prevent electromagnetic transmission escape or intrusion as well. The silencers and/or waveguides, for example, may include a honeycomb pattern. The silencers and/or waveguides, for example, may be made from brass, aluminum, steel, nickel, stainless steel, hardened steel, or any other metal. The honeycomb pattern, for example, may have a cell size with at least a first dimension of between 1/16″ to 1″ and second dimension of between ½ to 3″ such as, for example, a first dimension of ⅛″ and a second dimension of 1″; although, various other sizes may be used. Alternatively, other patterns could be, such as, for example, a circular, triangular, rectangular, or wavy pattern having similar dimensions as noted in the previous sentence. The acoustic insulation 750 may surround the waveguide 760 in the cavity within the panel box.

In the illustrated embodiment of FIG. 10, the acoustic insulation separates the waveguide 760 from the two EMI absorbers 732, 734. The two EMI absorbers 732, 734 and the waveguide 760 work together to control electromagnetic transmissions and can shield frequencies between 9 MHz and 20, 9 kHz and 40 GHZ, 9 MHz and 40 GHz. Additionally, the acoustic insulation along with the thickness of the overall shielded enclosure panel 700 work to stop sound transmission.

In some embodiments, the second metal sheet 724 is secured to the first metal sheet 722 via welding the end caps 726 to the perimeter of the metal sheets. Other forms of fastening are contemplated herein.

FIG. 11 is a perspective view of a shielded enclosure panel according to some embodiments. As can be seen, the shielded enclosure panel 700 resembles a six-sided box or panel box with the end caps 726 welded to each of the first metal sheet and the second metal sheet. In some embodiments, the welds go around the entire perimeter of the first and second metal sheet.

FIG. 12 is a front view of a plurality of shielded enclosure panels welded together according to some embodiments. A plurality of shielded enclosure panels 700 can be constructed and then welded together at welds 780 to form whatever size wall is needed. This allows for the shielded enclosure to be built to the size needed for a particular application.

Various thicknesses and sizes are contemplated herein. In some embodiments, the achievement of the sufficient sound transmission control is achieved when the thickness of the shielded enclosure panel is more than four inches. That is, the distance from the first metal sheet 22 and the second metal sheet 724. Depending on the needs of the overall system the thickness may be enlarged or shrunk to needs of the particular application. In some cases, the cavity may include three inches of acoustic insulation 750 and one inch of thickness waveguide 760. Various other sizes and configurations are contemplated herein. The thickness of the EMI absorbers may vary as well.

In some embodiments, the shielded enclosure panel 700 includes a first metal sheet 722 and a second metal sheet 724 coupled to the first metal sheet 722 and enclosing a cavity. The shielded enclosure panel 700 includes a first EMI absorber 732 on an inside surface of the first metal sheet 722 and a second EMI absorber 734 on an inside surface of the second metal sheet 724. In some embodiments, the shielded enclosure panel 700 includes a waveguide 760 positioned between the first and second EMI absorbers 732, 734 and acoustic insulation 750 positioned between the waveguide 760 and each EMI absorber 732, 734.

In some embodiments, the first and second metal sheets 722, 734 are welded closed to enclose the cavity. In some embodiments, the cavity is fully sealed such as, for example, around a periphery of the first metal sheet and a periphery of the second metal sheet. Additionally or alternatively a seal may be placed between the first metal sheet and the second metal sheet, and a plurality of bolts may be included to create a seal. In some embodiments, the EMI absorber 732, 734 is a flat absorber and includes ferrite. In some embodiments, the shielded enclosure panel 700 produces an electromagnetic transmission attenuation between 9 kHz and 40 gHz.

In some embodiments, the acoustic insulation 750 is mineral wool. In some embodiments, the waveguide is a honeycomb pattern and is ⅛″ by 1″ cell size. In some embodiments, there is an airgap in the waveguide cells of the waveguide 760. In some embodiments, the first and second metal sheets 722, 724 are 304 stainless steel. In some embodiments, the first and second metal sheets 722, 724 are 14-gauge steel.

In some embodiments, the shielded enclosure panel 700 includes a panel box including a first metal sheet 722 forming a first side of the panel box and a second metal sheet 724 forming a second side of the panel box with a gap therebetween. In some embodiments, the shielded enclosure panel 700 includes a first EMI absorber 732 on an inside surface of the first metal sheet 722 and a second EMI absorber 734 on an inside surface of the second metal sheet 724. In some embodiments, the shielded enclosure panel 700 includes a waveguide 760 positioned between the first and second EMI absorbers 732, 734 and acoustic insulation 750 positioned between the waveguide 760 and each EMI absorber 732, 734.

In some embodiments, the shielded enclosure panel 700 includes a first metal sheet 722 and a second metal sheet 724 coupled to the first metal sheet 722 and enclosing a cavity. In some embodiments, the shielded enclosure panel 700 includes a first EMI absorber 732 on an inside surface of the first metal sheet 722 and a second EMI absorber 734 on an inside surface of the second metal sheet 724. In some embodiments, the shielded enclosure panel 700 includes a waveguide 760 positioned between the first and second EMI absorbers 732, 734 and acoustic insulation 750 positioned between the waveguide 760 and each EMI absorber and wherein the shielded enclosure panel produces an electromagnetic transmission attenuation between 9 kHz and 40 gHz.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

The use of “adapted to” or “configured to” is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

1. A shielded enclosure panel comprising:
a first metal sheet;
a second metal sheet coupled to the first metal sheet and enclosing a cavity;
a first electromagnetic transmission interference (EMI) absorber on an inside surface of the first metal sheet;
a second EMI absorber on an inside surface of the second metal sheet; and
a waveguide positioned between the first and second EMI absorbers.
acoustic insulation positioned between the waveguide and each EMI absorber.

2. The shielded enclosure panel of claim 1, wherein the first and second metal sheets are welded closed to enclose the cavity.

3. The shielded enclosure panel of claim 1, wherein the EMI absorber is a flat absorber and comprises a ferrite.

4. The shielded enclosure panel of claim 1, wherein the shielded enclosure panel produces an electromagnetic transmission attenuation between 9 kHz and 40 gHz.

5. The shielded enclosure panel of claim 1, wherein the waveguide includes a plurality of cells that define an airgap.

6. The shielded enclosure panel of claim 1, wherein the acoustic insulation comprises mineral wool.

7. The shielded enclosure panel of claim 1, wherein the waveguide comprises a honeycomb pattern with cells having a first dimension of about ⅛″ and a second dimension of about 1″ cell size.

8. A shielded enclosure panel comprising:
a panel box comprising a first metal sheet forming a first side of the panel box and a second metal sheet forming a second side of the panel box with a gap therebetween, the panel box being fully sealed;
a first electromagnetic transmission interference (EMI) absorber on an inside surface of the first metal sheet
a second EMI absorber on an inside surface of the second metal sheet;
a waveguide positioned between the first and second EMI absorbers; and
acoustic insulation positioned between the waveguide and each EMI absorber.

9. The shielded enclosure panel of claim 8, wherein the first and second metal sheets are welded closed to enclose the cavity.

10. The shielded enclosure panel of claim 8, wherein the EMI absorber is a flat absorber and comprises ferrite.

11. The shielded enclosure panel of claim 8, wherein the shielded enclosure panel produces an electromagnetic transmission attenuation between 9 kHz and 40 gHz.

12. The shielded enclosure panel of claim 8, wherein the waveguide includes a plurality of cells that define an airgap.

13. The shielded enclosure panel of claim 8, wherein the acoustic insulation is mineral wool.

14. The shielded enclosure panel of claim 8, wherein the waveguide is a honeycomb pattern with a first cell size dimension of about ⅛″ and a second cell size dimension of about 1″.

15. A shielded enclosure panel comprising:
a first metal sheet;
a second metal sheet coupled to the first metal sheet and enclosing a cavity;
a first electromagnetic transmission interference (EMI) absorber on an inside surface of the first metal sheet
a second EMI absorber on an inside surface of the second metal sheet;
a waveguide positioned between the first and second EMI absorbers; and
acoustic insulation positioned between the waveguide and each EMI absorber wherein the shielded enclosure panel produces an electromagnetic transmission attenuation between 9 kHz and 40 gHz.

16. The shielded enclosure panel of claim 15, wherein the first metal sheet and the second metal sheet are welded together around a periphery of the first metal sheet and a periphery of the second metal sheet.

17. The shielded enclosure panel of claim 15, wherein either or both the first EMI absorber and the second EMI absorber comprises a flat absorber and comprises ferrite.

18. The shielded enclosure panel of claim 15, wherein the waveguide includes a plurality of cells that define an airgap.

19. The shielded enclosure panel of claim 15, wherein the acoustic insulation is mineral wool.

20. The shielded enclosure panel of claim 15, wherein the waveguide is a honeycomb pattern with a first cell size dimension of about ⅛″ and a second cell size dimension of about 1″.

21. A shielded enclosure panel comprising:
a first metal sheet;
a second metal sheet continuously bonded to the first metal sheet around a periphery of the first metal sheet and a periphery of the second metal sheet defining a cavity; and
a waveguide having a honeycomb pattern disposed within the cavity without being in contact with the first metal sheet or the second metal sheet.

22. The shielded enclosure panel of claim 21, further comprising a first electromagnetic transmission interference (EMI) absorber disposed within the cavity between the waveguide and either or both the first metal sheet and the second metal sheet.

23. The shielded enclosure panel of claim 21, further comprising an acoustic insulation disposed within the cavity between the waveguide and either or both the first metal sheet and the second metal sheet.

24. The shielded enclosure panel of claim 21, wherein the second metal sheet is welded to the first metal sheet around a periphery of the first metal sheet.

25. The shielded enclosure panel of claim 21, wherein the second metal sheet is bonded to the first metal sheet around a periphery of the first metal sheet with a gasket and plurality of bolts.

26. The shielded enclosure panel of claim 21, further comprising acoustic insulation disposed within the cavity between the waveguide and the either or both the first metal sheet and the second metal sheet.

27. The shielded enclosure panel of claim 26, wherein the acoustic insulation comprises mineral wool.

28. The shielded enclosure panel of claim 21, wherein the shielded enclosure panel produces an electromagnetic transmission attenuation between 9 kHz and 40 gHz.

29. The shielded enclosure panel of claim 21, wherein the shielded enclosure panel has an STC rating greater than 40.

30. A shielded enclosure panel comprising:
a first metal sheet;
a second metal sheet continuously bonded to the first metal sheet around a periphery of the first metal sheet and a periphery of the second metal sheet defining a cavity; and
a waveguide disposed within the cavity without being in contact with the first metal sheet or the second metal sheet;
wherein the shielded enclosure panel produces an electromagnetic transmission attenuation between 9 kHz and 40 gHz; and
wherein the shielded enclosure panel has an STC rating greater than 40.
